(19) United States
(12) Patent Application Publication
(10) Pub. No.: US 2026/0331187 A1
(43) Pub. Date: Oct. 22, 2026

(54) STORAGE DEVICE AND OPERATING METHOD OF THE STORAGE DEVICE

(71) Applicant: SK hynix Inc., Icheon-si Gyeonggi-do (KR)

(72) Inventors: Jong Wook KIM, Icheon-si Gyeonggi-do (KR); Jae Sung SIM, Icheon-si Gyeonggi-do (KR); Hyun Young SHIM, Icheon-si Gyeonggi-do (KR)

(73) Assignee: SK hynix Inc., Icheon-si Gyeonggi-do (KR)

(21) Appl. No.: 19/327,611

(22) Filed: Sep. 12, 2025

(30) Foreign Application Priority Data
Apr. 18, 2025 (KR) 10-2025-0050907

(51) Int. Cl. G11C 16/34

(52) U.S. Cl. CPC G11C 16/3418

(57) ABSTRACT

A storage device including a non-volatile memory device including a first memory block coupled to a plurality of select lines, and a controller controlling an operation of the non-volatile memory device. The controller is configured to monitor read count values corresponding to the plurality of select lines, respectively, during a read operation of the first memory block of the non-volatile memory device. The controller is configured to control the non-volatile memory device to perform an operation of relocating data stored in the first memory block, based on the read count values satisfying a first threshold value.

### CROSS-REFERENCE TO RELATED APPLICATION

The present application claims priority under 35 U.S.C. § 119(a) to Korean patent application number 10-2025-0050907 filed on Apr. 18, 2025, in the Korean Intellectual Property Office, the entire contents of which application is incorporated herein by reference.

### BACKGROUND

### 1. Technical Field

Various embodiments relate generally to an electronic device, and more particularly, to a storage device and an operating method of the storage device.

### 2. Related Art

A storage device stores data under the control of a host device, such as a computer, a smartphone, a smartpad, etc. Depending on devices storing data, a storage device includes a device which stores data on a magnetic disk, such as a hard disk drive (HDD), and a device which stores data on a semiconductor memory, especially a non-volatile memory, such as a solid state drive (SSD), a memory card, and the like.

The storage device may include a memory device in which data is stored and a memory controller which stores the data in the memory device. The memory device may be divided into a volatile memory and a non-volatile memory. Examples of the non-volatile memory include Read Only Memory (ROM), Programmable Read Only Memory (PROM), Electrically Programmable Read Only Memory (EPROM), Electrically Erasable Programmable Read Only Memory (EEPROM), Flash Memory (Flash), Phase-change Random Access Memory (PRAM), Magnetic Random Access Memory (MRAM), Resistive Random Access Memory (RRAM), Ferroelectric Random Access Memory (FRAM), and the like.

### SUMMARY

According to an embodiment, a storage device may include a non-volatile memory device including a first memory block coupled to a plurality of select lines. The storage device may include a controller configured to control an operation of the non-volatile memory device. The controller is configured to monitor read count values corresponding to the plurality of select lines, respectively, during a read operation of the first memory block of the non-volatile memory device, and configured to control the non-volatile memory device to perform an operation of relocating data stored in the first memory block, based on the read count values satisfying a first threshold value.

According to an embodiment, a storage device includes a first memory block coupled to a plurality of select lines. The method of operating the storage device may include performing a read operation on the first memory block, monitoring read count values corresponding to the plurality of select lines, respectively, and relocating data stored in the first memory block, based on the read count values satisfying a first threshold value.

According to an embodiment, a storage device includes a first memory block including a plurality of cell strings coupled to a plurality of select lines and a plurality of word lines. The method of operating the storage device includes applying a read voltage to a first word line of the plurality of word lines to perform a read operation on a first cell string. The method of operating the storage device includes increasing a first read count value for a first select line coupled to the first cell string. The method of operating the storage device includes relocating data stored in the first memory block, based on the first read count value satisfying a threshold value.

### BRIEF DESCRIPTION OF THE DRAWINGS

FIG. 1 is a diagram illustrating a storage device according to an embodiment of the present disclosure;

FIG. 2 is a diagram illustrating a configuration of a controller according to an embodiment of the present disclosure;

FIG. 3 is a diagram illustrating a configuration of a reliability management circuit according to an embodiment of the present disclosure;

FIG. 4 is a diagram illustrating one memory block of a plurality of memory blocks according to an embodiment of the present disclosure;

FIG. 5 is a diagram illustrating one memory block of a plurality of memory blocks according to an embodiment of the present disclosure;

FIG. 6 is a diagram illustrating a plurality of pages including memory blocks according to an embodiment of the present disclosure;

FIG. 7 is a diagram illustrating a representative page of a plurality of pages in a memory block;

FIG. 8 is a diagram illustrating at least two representative pages of a plurality of pages in a memory block;

FIG. 9 is a diagram illustrating a method of determining whether to perform a data relocation operation according to a test read according to an embodiment of the present disclosure;

FIG. 10 is a diagram illustrating a method of performing data relocation based on read count values corresponding to a plurality of select lines, respectively, according to an embodiment of the present disclosure;

FIG. 11 is a diagram illustrating a method of performing data relocation based on a test read operation according to an embodiment of the present disclosure;

FIG. 12 is a block diagram illustrating a memory card system to which a storage device according to an embodiment of the present disclosure is applied;

FIG. 13 is a block diagram illustrating an exemplary solid state drive (SSD) system to which a storage device according to embodiments of the present disclosure is applied; and

FIG. 14 is a block diagram illustrating a user system to which a storage device according to an embodiment of the present disclosure is applied.

### DETAILED DESCRIPTION

Specific structural or functional descriptions of examples of embodiments in accordance with concepts which are disclosed in this specification are illustrated to describe the examples of embodiments in accordance with the concepts and the examples of embodiments in accordance with the concepts may be carried out by various forms but the descriptions are not limited to the examples of embodiments described in this specification.

Various embodiments are directed to a storage device having an improved operation speed and a method of operating the storage device.

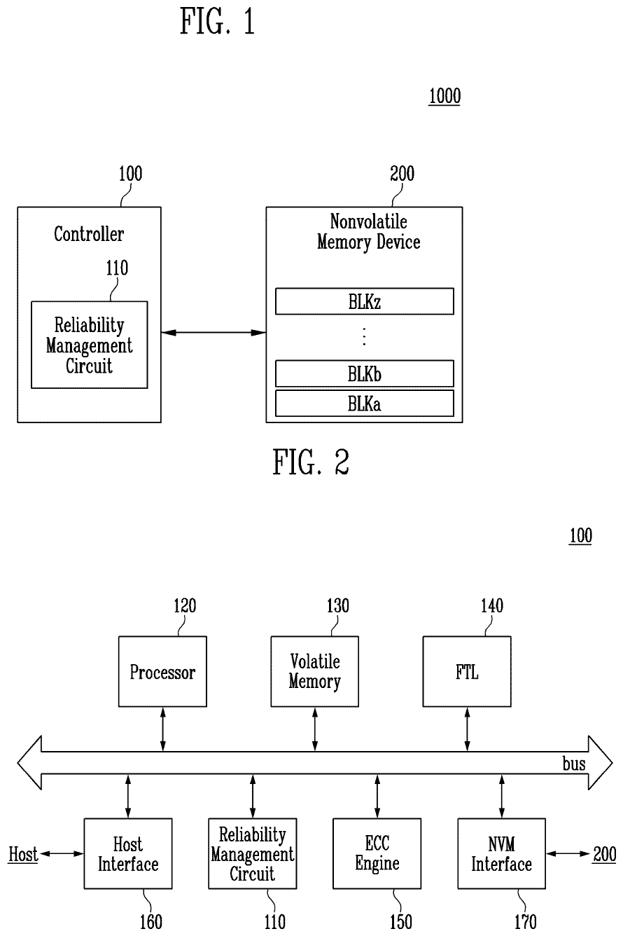

FIG. 1 is a diagram illustrating a storage device 1000 according to an embodiment of the present disclosure.

Referring to FIG. 1, the storage device 1000 may include a controller 100 and a non-volatile memory device 200.

The controller 100 may control operations of the non-volatile memory device 200. For example, the controller 100 may program data into the non-volatile memory device 200, or may perform a read operation on data stored in the non-volatile memory device 200. For example, the controller 100 may exchange a command, an address, and data with the non-volatile memory device 200.

The non-volatile memory device 200 may operate under the control of the controller 100. For example, when the non-volatile memory device 200 receives a program command from the controller 100, the non-volatile memory device 200 may program the received data to an address received from the controller 100. For example, when the non-volatile memory device 200 receives a read command from the controller 100, the non-volatile memory device 200 may perform a read operation on a region indicated by the address received from the controller 100, and may output data stored in the region to the controller 100.

While an embodiment in which the non-volatile memory device 200 is a flash memory device and the storage device 1000 is a solid state drive (SSD) will be described herein, the scope of the present disclosure is not limited thereto.

The non-volatile memory device 200 may include a plurality of memory blocks BLKa to BLKz. For example, each of the plurality of memory blocks BLKa to BLKz may include a plurality of cell strings coupled between a plurality of bit lines and a source line. Each of the plurality of cell strings may include a drain select transistor coupled to one of the plurality of bit lines, a source select transistor coupled to the source line, and a plurality of memory cells coupled between the drain select transistor and the source select transistor. For example, each of the plurality of memory blocks BLKa to BLKz may be coupled to a plurality of select lines. For example, each of the plurality of source select lines may be coupled to a gate electrode of a source select transistor included in each of the plurality of cell strings. For example, the plurality of memory cells may store data, and a read operation or a program operation may be performed through the plurality of word lines. For example, a read operation or a program operation may be performed on a page-by-page basis on each of the plurality of memory cells, while an erase operation may be performed thereon on a block-by-block basis. For example, each of the plurality of memory cells may be a charge trap flash (CTF) memory cell.

According to an embodiment, threshold voltages of the memory cells may change due to various factors. As the threshold voltages of the memory cells change, errors may occur in data stored in the memory cells.

For example, the amount of threshold voltage change of the memory cells may be determined based on retention characteristics. The retention characteristics may be related to the duration during which a memory cell can retain stored data without loss after the data has been stored. Due to the process characteristics of the non-volatile memory device 200, the retention characteristics of the plurality of memory blocks BLKa to BLKz may differ from each other. For example, differences in retention characteristics of the memory cells may result in varying levels of reliability of the data stored in the memory cells.

For example, as a charge loss phenomenon occurs, the threshold voltage of the programmed memory cell may be lowered. The charge loss phenomenon may refer to the loss of charge stored in the memory cell over time from the time the memory cell was programmed, resulting in a lower threshold voltage. Retention characteristics may be determined based on the amount of charge loss that occurs in a memory block over a specific time period.

The controller 100 may include a reliability management circuit 110. The reliability management circuit 110 may perform various operations to control the reliability of data stored in the non-volatile memory device 200. For example, the reliability management circuit 110 may perform a data relocation operation of data stored in a first memory block of the plurality of memory blocks BLKa to BLKz.

According to an embodiment, the operation of relocation of the data in the first memory block by the reliability management circuit 110 may include a read reclaim operation or a garbage collection operation. However, the present disclosure is not limited thereto.

For example, the reliability management circuit 110 may move valid data stored in a memory block to another memory block before an uncorrectable error occurs in the data stored in the memory block by a read reclaim operation.

For example, the reliability management circuit 110 may, through a garbage collection operation, invalidate data stored in an existing memory block after copying valid data in the memory block to a new block. The reliability management circuit 110 may ensure free blocks in the non-volatile memory device 200 through the garbage collection operation. For example, a free block may refer to a memory block which includes only invalid data.

For example, data relocation operations performed by the reliability management circuit 110 may increase the reliability of data stored in the plurality of memory blocks BLKa to BLKz. However, as the data relocation operations are performed, the overhead of the controller 100 may increase and the performance of the storage device 1000 may decrease.

According to an embodiment, the reliability management circuit 110 may control the non-volatile memory device 200 to perform a data relocation operation for the plurality of memory blocks BLKa to BLKz based on read count values satisfying a first threshold value. For example, the reliability management circuit 110 may determine the read count values based on the plurality of select lines. The reliability management circuit 110 may monitor the read count values respectively corresponding to the plurality of select lines during a read operation for each of the plurality of memory blocks BLKa to BLKz.

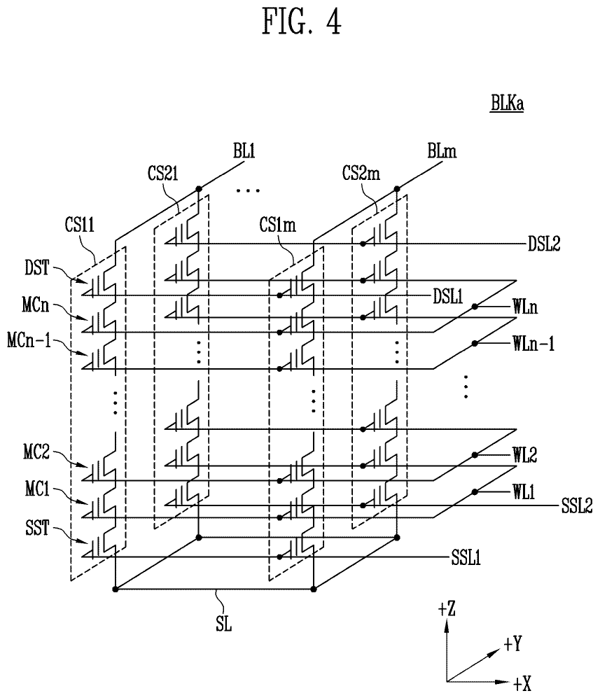

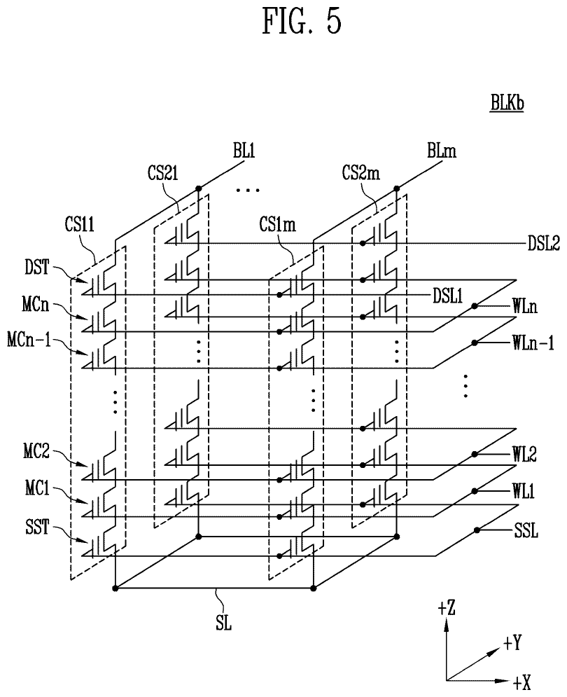

For example, the reliability management circuit 110 may monitor a read count value corresponding to each of the plurality of select lines by counting the number of read operations corresponding to a select line coupled to a first cell string on which a read operation is performed. For example, the plurality of select lines may include a plurality of source select lines each coupled to a gate electrode of a source select transistor included in each of the plurality of cell strings. For example, the plurality of cell strings may be selectively coupled to the source line by a voltage applied to the plurality of select lines. For example, each of the plurality of source select lines may be coupled to two or more different cell strings coupled to the same bit line among the plurality of cell strings. The plurality of select lines will be described below with reference to FIGS. 4 and 5.

According to an embodiment, the reliability management circuit 110 may perform a test read operation on the first memory block based on read count values. Based on the results of the test read operation, the reliability management circuit 110 may perform a data relocation operation on the first memory block.

According to an embodiment, the reliability management circuit 110 may perform an operation of relocating data in the first memory block whenever one of the read count values for the first memory block reaches a first cycle. For example, the reliability management circuit 110 may control the non-volatile memory device 200 to perform a test read operation on the first memory block each time one of the read count values reaches the first cycle.

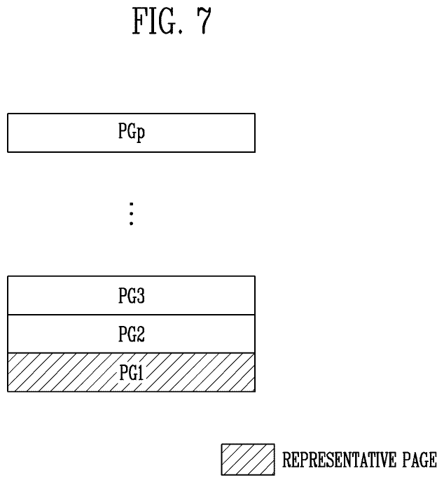

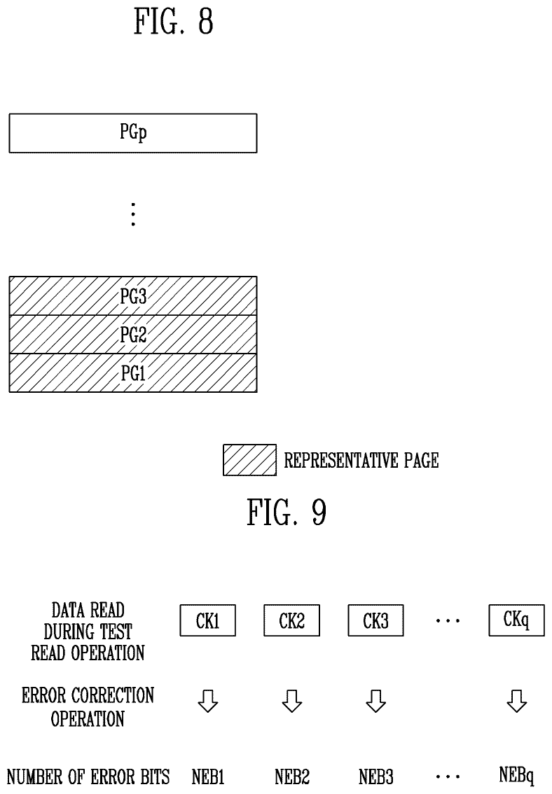

For example, the first memory block may include a plurality of pages, and the reliability management circuit 110 may control the non-volatile memory device to perform a test read operation on at least one representative page of the plurality of pages. For example, a representative page may refer to a page with poor retention characteristics. The representative page will be described in more detail below with reference to FIGS. 7 and 8.

For example, the reliability management circuit 110 may, based on the test read operation, read first data of the first memory block and determine whether the number of error bits included in the first data satisfies a second threshold value. For example, based on whether the number of error bits included in the first data satisfies the second threshold value, the reliability management circuit 110 may control the non-volatile memory device 200 to perform an operation of relocating the data stored in the first memory block. The test read operation will be described in more detail below with reference to FIG. 9.

In an embodiment, as the reliability management circuit 110 performs the data relocation operation based on each read count value of the respective select lines, the number of data relocation operations may be reduced as compared to using each read count value of the respective data blocks. In an embodiment, as the reliability management circuit 110 performs a data relocation operation based on the results of the test read operation, the number of data relocation operations may be reduced. In an embodiment, as the number of data relocation operations is reduced, the overhead of the controller 100 may be reduced and the performance of the storage device 1000 may be improved.

FIG. 2 is a diagram illustrating the configuration of the controller 100 according to an embodiment of the present disclosure.

The controller 100 may include the reliability management circuit 110, a processor 120, a volatile memory device 130, a flash translation layer (FTL) 140, an error correction code (ECC) engine 150, a host interface 160, and a non-volatile memory (NVM) interface 170. The reliability management circuit 110, the processor 120, the volatile memory device 130, the flash translation layer 140, the ECC engine 150, the host device interface 160, and the non-volatile memory interface 170 may be coupled to each other via a bus.

The reliability management circuit 110 may perform various operations to control the reliability of data stored in the non-volatile memory device 200 (see FIG. 1). For example, the reliability management circuit 110 may perform a data relocation operation of data stored in a first memory block of the plurality of memory blocks BLKa to BLKz. Because the reliability management circuit 110 is described above with reference to FIG. 1, a detailed description of the reliability management circuit 110 will be omitted.

The processor 120 may control the overall operation of the controller 100. For example, the reliability management circuit 110 may be provided in software form and driven by the processor 120.

The volatile memory device 130 may serve as a main memory, a buffer memory, a cache memory, etc. of the controller 100. The volatile memory device 130 may store read data and read count values received from the non-volatile memory device 200. For example, the volatile memory device 130 may store information for managing memory space of the non-volatile memory device 200, program and erase (P/E) cycles, erase counts (EC), loop counts (LC), and the like for each memory block.

The flash translation layer 140 may translate a logical address received from an external device, such as a host, into a physical address used by the non-volatile memory device 200.

In an embodiment, the data relocation operation of the reliability management circuit 110 may be performed via the flash translation layer 140. For example, the flash translation layer 140 may perform a read reclaim operation or a garbage collection operation on the non-volatile memory device 200.

In an embodiment, the reliability management circuit 110 and the flash translation layer 140 may be implemented in the form of firmware. For example, the processor 120 may implement the reliability management circuit 110 and the flash translation layer 140 by loading instructions stored in the non-volatile memory device 200 into the volatile memory device 130 and executing the loaded instructions.

The ECC engine 150 may detect and correct errors in data read data from the non-volatile memory device 200. For example, the ECC engine 150 may decode the read data according to an error correction code (ECC). For example, it will be understood that the error correction code used by the ECC engine 150 may include a variety of different error correction codes, such as the Bose-Chaudhuri-Hocquenghem (BCH) code, the Reed-Solomon code, the Hamming code, and the low-density parity-check (LDPC) code.

According to an embodiment, a page may include a plurality of chunks, and the ECC engine 150 may perform an error correction operation on one chunk. According to an embodiment, the ECC engine 150 may have a predetermined level of error correction capability. The ECC engine 150 may treat data having an error level which exceeds the error correction capability as uncorrectable data. For example, when the number of error bits among data bits in one chunk satisfies a guaranteed number, the ECC engine 150 might not be able to correct the errors in the chunk. The error correction operation may fail when the data bits of a chunk include a greater number of error bits than the guaranteed number. For example, the error correction operation may succeed when the data bits of the chunk are less than or equal to the guaranteed number of error bits. The word “predetermined” as used herein with respect to a parameter, such as a predetermined level or representative page, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

According to an embodiment, the reliability management circuit 110 may read first data, determine whether the number of error bits included in the first data satisfies a second threshold value, and relocate data in the first memory block based on the determination. For example, the reliability management circuit 110 may read the first data of the first chunk. For example, the reliability management circuit 110 may determine, by the ECC engine 150, the number of error bits included in the first data of the first chunk. The reliability management circuit 110 may determine, by the ECC engine 150, whether the number of error bits satisfies a second threshold value. For example, the threshold value may be less than a guaranteed number of error bits based on the error correction capability of the ECC engine 150. For example, the threshold value may be 70% of the number of error bits guaranteed based on the error correction capability of the ECC engine 150.

The controller 100 may communicate with the host through the host interface 160. For example, the controller 100 may send and receive packets to and from the host via the host interface 160. Packets sent to the host interface 160 from the host may include commands or data to be programmed into the non-volatile memory device 200, and packets sent from the host interface 160 to the host may include responses to commands or data read from the non-volatile memory device 200. For example, the host interface 160 may be implemented based on at least one of a variety of interfaces, such as Serial ATA (SATA), Peripheral Component Interconnect Express (PCIe), Serial Attached SCSI (SAS), Nonvolatile Memory express (NVMe), Universal Flash Storage (UFS), Compute Express Link (CXL), and the like.

Through the non-volatile memory interface 170, the controller 100 may communicate with the non-volatile memory device 200. For example, the non-volatile memory interface 170 may transfer data to be programmed into the non-volatile memory device 200, or may receive read data from the non-volatile memory device 200. For example, the non-volatile memory interface 170 may be implemented based on a NAND interface. For example, the non-volatile memory interface 170 may be implemented to comply with standard protocols such as Toggle or Open NAND Flash Interface (ONFI).

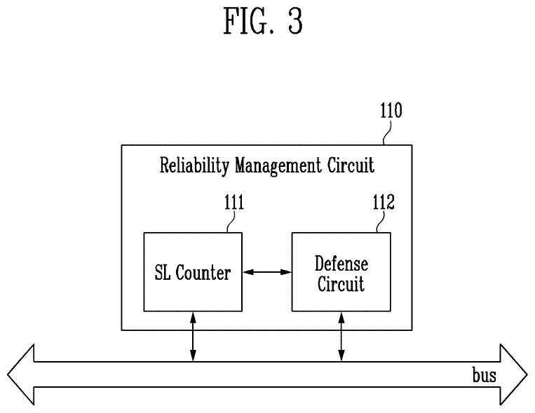

FIG. 3 is a diagram illustrating a configuration of the reliability management circuit 110 according to an embodiment of the present disclosure. Hereinafter, a description will be given with reference to FIG. 2 as well.

Referring to FIG. 3, the reliability management circuit 110 may include a select line counter 111 and a defense circuit 112.

The select line counter 111 may count the number of read operations corresponding to each of a plurality of select lines of the plurality of memory blocks included in the non-volatile memory device 200, and may monitor each read count value corresponding to the respective select lines. For example, each time a read operation is performed with respect to a first select line, the select line counter 111 may increment a first read count value. For example, each time a read operation is performed with respect to a second select line, the select line counter 111 may increment a second read count value. For example, each time a read operation is performed with respect to an nth select line, the select line counter 111 may increment an nth read count value, where n is a natural number.

For example, the select line counter 111 may include a memory and store read count values in the memory. In another example, the select line counter 111 may store and maintain the read count values in the volatile memory device 130 or the non-volatile memory device 200.

For example, the select line counter 111 may be disposed at each of the plurality of select lines to count the number of read operations corresponding to each of the plurality of select lines. In another example, the select line counter 111 may receive read count values from the non-volatile memory device 200 through the non-volatile memory interface 170, and may monitor the read count values for the plurality of select lines, respectively.

The defense circuit 112 may determine which of the read count values reaches a first cycle. In an embodiment, the ‘first cycle’ refers to a predefined read count threshold value. For example, once the SL counter 111 reaches a certain threshold or first cycle for a select line or plurality of select lines within a memory block, the SL counter 111 notifies the defense circuit 112 that read disturb may start becoming a risk and, as such, the defense circuit 112 may perform an operation of relocating the data in the memory block to another memory block. According to an embodiment, the defense circuit 112 may perform an operation of relocating the data in the memory block whenever one of the read count values reaches the first cycle. For example, the defense circuit 112 may relocate data in a first memory block including the first select line when the read count value of the first select line reaches the first cycle. For example, the operation of relocating the data may include a read reclaim operation or a garbage collection operation.

In another example, the defense circuit 112 may perform a test read operation whenever one of the read count values reaches the first cycle. For example, the defense circuit 112 may perform a test read operation on the first memory block including the first select line when the read count value of the first select line reaches the first cycle. For example, the defense circuit 112 may perform the test read operation on a representative page of the first memory block. For example, the representative page may refer to a weak page determined based on retention characteristics. Based on the test read operation on the representative page, the defense circuit 112 may perform a data relocation operation. For example, based on the test read operation, the defense circuit 112 may read the first data of the first chunk included in the representative page and determine whether the number of error bits included in the first data satisfies a second threshold value. Based on whether the number of error bits included in the first data satisfies the second threshold value, the defense circuit 112 may control the non-volatile memory device 200 to perform an operation of relocating the data stored in the first memory block.

According to an embodiment, the defense circuit 112 may initialize the first read count value when the first read count value among the read count values reaches the first cycle. For example, the first read count value may be a read count value for the first select line. After the first read count value is initialized, when read operations are performed with respect to the first select line, the select line counter 111 may monitor the first read count value by counting the number of read operations. For example, when the first read count value reaches the first cycle again, the defense circuit 112 may perform a data relocation operation or a test read operation and initialize the first read count value.

FIG. 4 is a diagram illustrating one memory block of a plurality of memory blocks according to an embodiment of the present disclosure.

Referring to FIG. 4, a memory block BLKa may include a plurality of cell strings CS11 to CS1m and CS21 to CS2m. For example, the plurality of cell strings CS11 to CS1m and CS21 to CS2m may be coupled between a plurality of bit lines BL1 to BLm and a source line SL.

In an embodiment, the memory block BLKa as described with reference to FIG. 4 is an example. The number of cell strings may be increased or decreased, and the number of rows and columns defined by the cell strings may be increased or decreased according to the number of cell strings. Further, the respective numbers of cell transistors (DST, MC, SST, etc.) of the memory block BLKa may be increased or decreased, and the height of the memory block BLKa may be increased or decreased according to the numbers of cell transistors. Further, the numbers of lines (DSL, WL, SSL, etc.) coupled to the cell transistors may be increased or decreased according to the numbers of cell transistors.

Each of the plurality of cell strings CS11 to CS1m and CS21 to CS2m may extend along a +Z direction. Each of the plurality of cell strings CS11 to CS1m and CS21 to CS2m may include at least one source select transistor SST, first to nth memory cells MC1 to MCn, and at least one drain select transistor DST stacked on a substrate (not shown) below the memory block BLK1. For example, each of the plurality of cell strings CS11 to CS1m and CS21 to CS2m may include the drain select transistor DST coupled to one of the plurality of bit lines BL1 to BLm and the source select transistor SST coupled to the source line SL. For example, each of the plurality of cell strings CS11 to CS1m and CS21 to CS2m may include the first to nth memory cells MC1 to MCn coupled between the drain select transistor DST and source select transistors SST.

The source select transistor SST of each cell string may be coupled between the source select line SL and the memory cells MC1 to MCn. Source select transistors of cell strings arranged in the same row may be coupled to the same source select line. Source select transistors of the cell strings CS11 to CS1m arranged in a first row may be coupled to a first source select line SSL1. Source select transistors of the cell strings CS21 to CS2m arranged in a second row may be coupled to a second source select line SSL2. For example, each of the plurality of source select lines SSL1 and SSL2 may be coupled with gate electrodes of source select transistors respectively included in the plurality of cell strings CS11 to CS1m and CS21 to CS2m.

Referring to FIG. 1 together, according to an embodiment, the reliability management circuit 110 may monitor read count values respectively corresponding to the plurality of select lines. For example, the plurality of select lines may include the plurality of source select lines SSL1 and SSL2. For example, the reliability management circuit 110 may monitor each read count value coupled to the respective source select lines SSL1 and SSL2. For example, the reliability management circuit 110 may monitor a first read count value for the first source select line SSL1 and a second read count value for the second source select line SSL2.

The first to nth memory cells MC1 to MCn of each cell string may be coupled in series between the source select transistor SST and the drain select transistor DST. Gates of the first to nth memory cells MC1 to MCn may be coupled to the first to nth word lines WL1 to WLn, respectively.

The drain select transistor DST of each cell string may be coupled between the corresponding bit line and the memory cells MC1 to MCn. Drain select transistors of cell strings arranged in a row direction may be coupled to a drain select line extending in the row direction. The drain select transistors of the cell strings CS11 to CS1m in the first row may be coupled to a first drain select line DSL1. The drain select transistors of the cell strings CS21 to CS2m in the second row may be coupled to a second drain select line DSL2.

In the cell strings arranged in the row direction, memory cells coupled to the same word line may constitute one page. For example, among the cell strings CS11 to CS1m in the first row, the memory cells coupled to the first word line WL1 may constitute one page. The memory cells coupled to the first word line WL1 of the cell strings CS21 to CS2m in the second row may constitute another page. By selecting one of the drain select lines DSL1 and DSL2, the cell strings arranged in one row direction may be selected. By selecting one of the word lines WL1 to WLn, one page among the selected cell strings may be selected. For example, when memory cells coupled to the same word line constitute one page, the memory cells may be single level cells (SLC) where one data bit is stored per cell.

According to an embodiment, memory cells coupled to the same word line within cell strings arranged in a row direction may include a plurality of pages. For example, when the memory cells store a plurality of data bits, the plurality of data bits may be stored on the plurality of pages of the memory cells, respectively. For example, in a Multi-Level Cell (MLC) where one memory cell stores two bits of data, memory cells coupled to the same word line may constitute two pages. For example, in a Triple Level Cell (TLC) scheme, where one memory cell stores three bits of data, memory cells coupled to the same word line may constitute three pages. For example, in a quadruple level cell (QLC) scheme where a single memory cell may store four bits of data, memory cells coupled to the same word line may constitute four pages.

Referring to FIG. 1 together, according to an embodiment, the controller 100 may control the non-volatile memory device 200 to apply a voltage to the plurality of word lines WL1 to WLn to perform a read operation. According to an embodiment, when the read operation is performed on the memory cells coupled to the first word line WL1 in the cell strings CS11 to CS1m in the first row, the reliability management circuit 1100 may monitor a first read count value corresponding to the first source select line SSL1 by counting the read operations corresponding to the first source select line SSL1 coupled to the memory cells coupled to the first word line WL1. For example, the source select line for which the read operations are counted may be the first source select line SSL1 which is coupled to the memory cells coupled to the first word line WL1 without passing through the bit line or the source line SL. In other words, the reliability management circuit 110 may monitor the read count values corresponding to the source select lines SSL1 and SSL2, respectively, by counting the number of read operations corresponding to each source select line coupled to the cell string in which the read operations are performed.

FIG. 5 is a diagram illustrating one memory block of a plurality of memory blocks according to an embodiment of the present disclosure.

Referring to FIG. 5, the source select transistors of the plurality of cell strings CS11 to CS1m and CS21 to CS2m may be coupled in common to a single source select line SSL. For example, in addition to the plurality of cell strings CS11 to CS1m and CS21 to CS2m, a memory block BLKb may further include cell strings (not shown) coupled between the plurality of bit lines BL1 to BLm and the source line SL. For example, the memory block BLKb may further include cell strings arranged in a third row (not shown) and a fourth row (not shown), and the source select transistors of the cell strings in the third row and the fourth row may be commonly coupled to the source select line SSL. For example, the source select transistors of the memory block BLKb may be commonly coupled to one source select line SSL.

According to an embodiment, the memory block BLKb may include a plurality of source select lines, and each of the plurality of source select lines may be coupled to two or more different cell strings coupled to the same bit line among the plurality of cell strings. For example, the cell strings in the first and second rows may be coupled to the first source select line, and the cell strings in the third and fourth rows may be coupled to the second source select line.

In other words, the memory block BLKb of FIG. 5 may be an equivalent circuit similar to the memory block BLKa of FIG. 4, except that the source select transistors of the plurality of cell strings CS11 to CS1m and CS21 to CS2m are commonly coupled to the single source select line SSL.

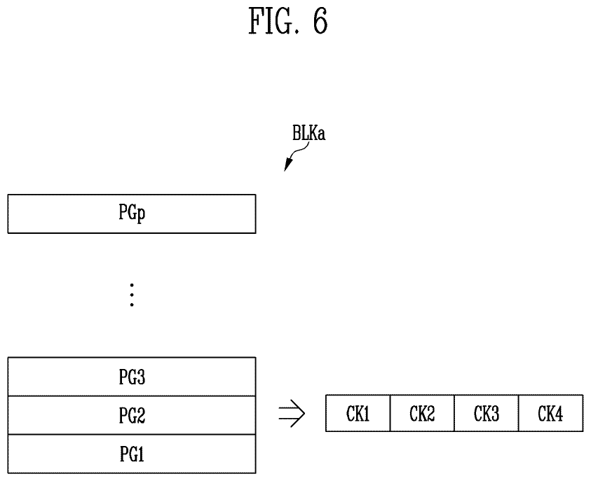

FIG. 6 is a diagram illustrating a plurality of pages included in a memory block according to an embodiment of the present disclosure.

Referring to FIG. 6, the memory block BLKa may include a plurality of pages PG1 to PGp. As described in FIG. 4, it will be understood that one page includes memory cells coupled to one word line. For example, program operations and read operations of the non-volatile memory device 200 as shown in FIG. 2 may be performed on a page-by-page basis. Each page may include a plurality of chunks CK1 to CK4. The ECC engine 150 as shown in FIG. 2 may perform error correction operations on a chunk-by-chunk basis.

FIG. 7 is a diagram illustrating a representative page of a plurality of pages in a memory block.

Referring to FIG. 7, the page PG1 among the first to pth pages PG1 to PGp may be set as a representative page. The representative page may be predetermined. The representative page may be determined with reference to manufacturing processes, operation characteristics, applicable products, and the like of the non-volatile memory device 200 (see FIG. 1). The representative page may be determined as a page which is expected to have the lowest reliability among the first to pth pages PG1 to PGp. For example, the representative page may refer to a page with poor retention characteristics. For example, among the first to pth pages PG1 to PGp, a page adjacent to drain select transistors (see FIG. 4) may be determined as the representative page. In another example, among the first to pth pages PG1 to PGp, a page adjacent to source select transistors (see FIG. 4) may be determined as a representative page.

According to an embodiment, the reliability management circuit 110 (see FIG. 1) may perform a test read operation on the representative page. Based on the test read operation, the reliability management circuit 110 may determine whether to perform a data relocation operation on the memory block including the representative page.

FIG. 8 is a diagram illustrating at least two representative pages of a plurality of pages in a memory block.

Referring to FIG. 8, the plurality of pages PG1 to PG3 of the first to pth pages PG1 to PGp are set as representative pages.

According to an embodiment, the reliability management circuit 110 (see FIG. 1) may perform a test read operation on the plurality of representative pages. Based on the test read operation, the reliability management circuit 110 may determine whether to perform a data relocation operation on a memory block including the plurality of representative pages. For example, the more pages that are set as representative pages, the more accurately the characteristics of the memory cells in the corresponding memory block may be reflected in a test read. For example, the more pages that are set as representative pages, the more accurately the degree of retention of data stored in the memory cells in the corresponding memory block may be determined by test read operations.

FIG. 9 is a diagram illustrating a method of determining whether to perform a data relocation operation according to a test read according to an embodiment of the present disclosure.

Referring to FIG. 9, when one of the read count values of the first memory block have reached a first cycle, the reliability management circuit 110 (see FIG. 1) may read first to qth chunks CK1 to CKq included in the first memory block through a test read operation. The first to qth chunks CK1 to CKq may be included in a single representative page as described above with reference to FIG. 7.

The first to qth chunks CK1 to CKq may be included in two or more representative pages, as described with reference to FIG. 8. In another example, the first to qth chunks CK1 to CKq may be included in all pages of the memory block.

The ECC engine 150 as shown in FIG. 2 may perform error correction operations on the first to qth chunks CK1 to CKq. Accordingly, the numbers of error bits, NEB1 to NEBq, corresponding to the first to qth chunks CK1 to CKq may be calculated.

The presence of any number of error bits, NEB1 to NEBq, which exceeds a threshold value may indicate that some of the data stored in the storage area has become corrupted. In other words, the retention of some of the data stored in the storage area may be degraded. For example, the threshold value may be 70% of the guaranteed number of error bits based on the error correction capability of the ECC engine 150. When any number of error bits NEB1 to NEBq is greater than the threshold value, the reliability management circuit 110 may perform a data relocation operation.

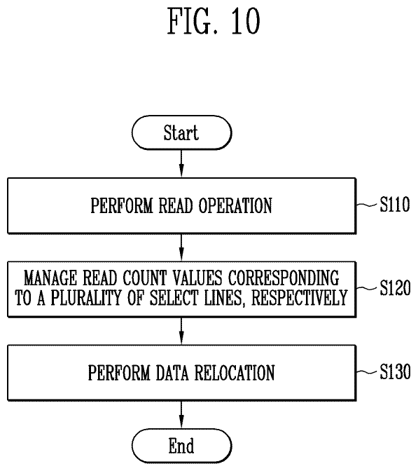

FIG. 10 is a diagram illustrating a method of performing data relocation based on read count values respectively corresponding to a plurality of select lines according to an embodiment of the present disclosure. Hereinafter, a description will be given with reference to FIG. 1 as well.

Referring to FIG. 10, at operation S110, a read operation may be performed. For example, the controller 100 may perform a read operation on a first memory block included in the non-volatile memory device 200. For example, the first memory block may include a plurality of select lines and a plurality of cell strings coupled to a plurality of word lines, and the controller 100 may perform a read operation on a first cell string by applying a read voltage to a first word line of the plurality of word lines.

At operation S120, read count values corresponding to the plurality of select lines, respectively, may be monitored. For example, the controller 100 may monitor each read count value corresponding to the respective select lines during a read operation to the first memory block. For example, the controller 100 may count the number of read operations with respect to a select line corresponding to a read operation among the plurality of select lines, and may monitor the read count values respectively corresponding to the plurality of select lines. For example, the controller 100 may increment a first read count value for the first select line coupled to the first cell string on which the read operations are performed, and may monitor the first read count value.

According to an embodiment, the first memory block may include a plurality of cell strings coupled between a plurality of bit lines and a source line. Each of the plurality of cell strings may include a drain select transistor coupled to one of the plurality of bit lines, a source select transistor coupled to the source line, and a plurality of memory cells coupled between the drain select transistor and the source select transistor. The plurality of select lines for which the controller monitors the read count values may include a plurality of source select lines each coupled to a gate electrode of a source select transistor included in each of the plurality of cell strings. For example, the plurality of select lines may include the plurality of source select lines such that the plurality of cell strings are selectively coupled to the source line by an applied voltage. For example, the controller 100 may count the number of read operations with respect to the source select line coupled to the first cell string on which the read operations are performed, and may monitor a read count value corresponding to each of the plurality of select lines. For example, each of the plurality of source select lines may be coupled to two or more different cell strings coupled to the same bit line among the plurality of cell strings.

At operation S130, data relocation may be performed. For example, the controller 100 may control the non-volatile memory device 200 to perform an operation of relocating data stored in the first memory block based on the read count values satisfying a first threshold value. For example, the controller 100 may perform a test read operation on the first memory block based on the read count values satisfying a first threshold value, and may perform the data relocation operation based on a result of the test read operation. For example, the data relocation operation may include performing a read reclaim operation or a garbage collection operation on the data stored in the first memory block.

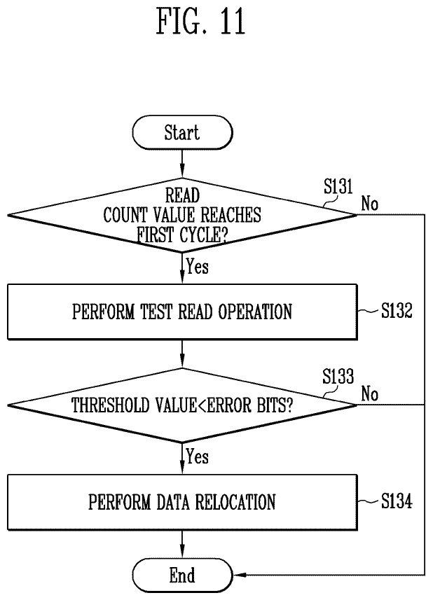

FIG. 11 is a diagram illustrating a method of performing data relocation based on a test read operation according to an embodiment of the present disclosure. Hereinafter, a description will be given with reference to reference to FIG. 1 as well.

Referring to FIG. 11, at operation S131, it may be determined whether a read count value reaches a first cycle. For example, the controller 100 may determine whether the read count value has reached the first cycle, and when the read count value has reached the first cycle, the controller 100 may perform operation S132. For example, when the read count value has not reached the first cycle, the procedure may end.

At operation S132, a test read operation may be performed. For example, the controller 100 may perform the test read operation whenever one of the read count values respectively corresponding to the plurality of select lines included in the first memory block reaches the first cycle. For example, the test read operation may be performed for at least one representative page of the plurality of pages included in the first memory block.

At operation S133, it may be determined whether the number of error bits in the data for which the test read operation is performed satisfies a second threshold value. For example, the controller 100 may read first data of the first memory block and determine whether the number of error bits included in the first data satisfies the second threshold value. For example, the first data may be included in the representative page on which the test read operation is performed. For example, the threshold value may be determined based on an error correction capability of the controller 100. For example, when the number of error bits satisfies the second threshold value, operation S134 may be performed. For example, when the number of error bits is less than the second threshold value, the procedure may be terminated.

At operation S134, data relocation may be performed. For example, the controller 100 may control the non-volatile memory device 200 to perform an operation of relocating the data stored in the first memory block based on the read count values. For example, based on the read count values, the controller 100 may perform the test read operation on the first memory block and perform the data relocation operation based on the results of the test read operation. For example, the data relocation operation may include performing a read reclaim operation or a garbage collection operation on the data stored in the first memory block.

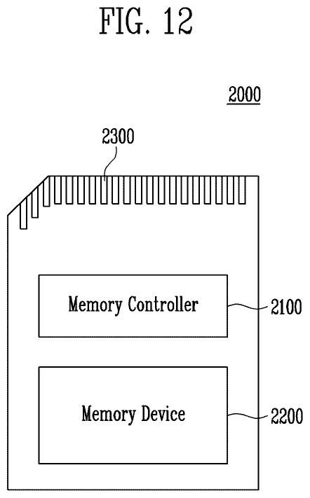

FIG. 12 is a block diagram illustrating a memory card system 2000 to which a storage device according to an embodiment is applied.

Referring to FIG. 12, the memory card system 2000 may include a memory controller 2100, a memory device 2200, and a connector 2300.

The memory controller 2100 may be coupled to the memory device 2200. The memory controller 2100 may access the memory device 2200. For example, the memory controller 2100 may control read, program, erase, and background operations of the memory device 2200. The memory controller 2100 may provide an interface between the memory device 2200 and the host. The memory controller 2100 may drive firmware for controlling the memory device 2200. For example, the memory device 2200 may be implemented in the same manner as the memory device 200 as described above with reference to FIG. 1.

In an embodiment, the memory controller 2100 may include components, such as a Random Access Memory (RAM), a processing unit, a host interface, a flash interface, and an ECC circuit. For example, the memory controller 2100 may be configured in the same manner as the controller 100 as described above with reference to FIG. 1.

The memory controller 2100 may communicate with an external device through the connector 2300. The memory controller 2100 may communicate with the external device (e.g., the host) based on a specific communication protocol. In an embodiment, the memory controller 2100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. In an embodiment, the connector 2300 may be defined by at least one of the above-described various communication protocols.

In an embodiment, the memory device 2200 may be implemented as one of various non-volatile memory devices, such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and a Spin Transfer Torque Magnetic RAM (STT-MRAM).

The memory controller 2100 and the memory device 2200 may be integrated into a single semiconductor device to form a memory card. For example, the memory controller 2100 and the memory device 2200 may be integrated into a single semiconductor device and form a memory card, such as a personal computer memory card international association (PCMCIA), a compact flash card (CF), a smart media card (SM or SMC), a memory stick multimedia card (MMC, RS-MMC, or MMCmicro), a SD card (SD, miniSD, microSD, or SDHC), a universal flash storage (UFS), and the like.

According to an embodiment, the memory controller 2100 may monitor read count values corresponding to a plurality of select lines of the memory device 2200, respectively, and may control the memory device 2200 to perform an operation of relocating data stored in the first memory block based on the read count values satisfying a first threshold value. For example, the memory controller 2100 may include the reliability management circuit 110 as described in FIG. 1.

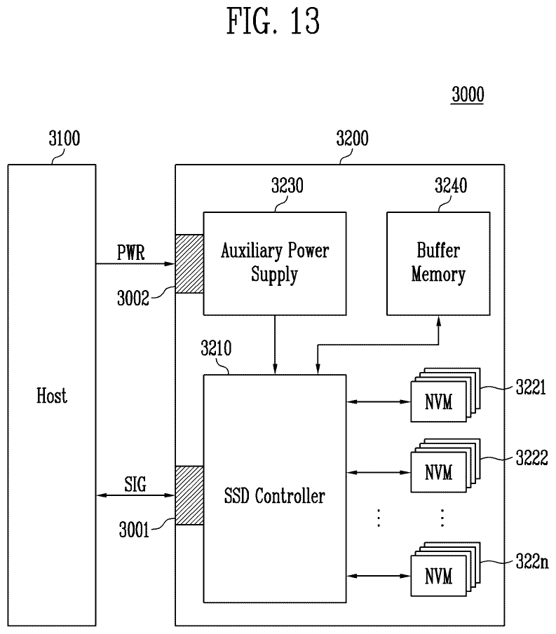

FIG. 13 is a block diagram illustrating a solid state drive (SSD) system 3000 to which a storage device according to an embodiment is applied.

Referring to FIG. 13, the SSD system 3000 may include a host 3100 and an SSD 3200. The SSD 3200 may exchange signals SIG with the host 3100 through a signal connector 3001 and may receive power through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform the function of the memory controller 100 as described above with reference to FIG. 1.

The SSD controller 3210 may control the plurality of flash memories 3221 to 322n in response to the signals SIG received from the host 3100. In an embodiment, the signals SIG may be signals based on the interfaces of the host 3100 and the SSD 3200. For example, the signals SIG may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), WiFi, Bluetooth, and non-volatile memory express (NVMe) interfaces.

The auxiliary power supply 3230 may be coupled to the host 3100 through the power connector 3002. The auxiliary power supply 3230 may be supplied and charged with power from the host 3100. The auxiliary power supply 3230 may supply the power of the SSD 3200 when power is not smoothly supplied from the host 3100. In an embodiment, the auxiliary power supply 3230 may be positioned inside or outside the SSD 3200. For example, the auxiliary power supply 3230 may be disposed in a main board and may supply auxiliary power to the SSD 3200.

The buffer memory 3240 may function as a buffer memory of the SSD 3200. For example, the buffer memory 3240 may temporarily store data received from the host 3100 or data received from the plurality of flash memories 3221 to 322n or may temporarily store metadata (e.g., mapping tables) of the flash memories 3221 to 322n. The buffer memory 3240 may include volatile memories such as DRAM, SDRAM, DDR SDRAM, LPDDR SDRAM, and GRAM, or non-volatile memories such as FRAM, ReRAM, STT-MRAM, and PRAM.

According to an embodiment, the SSD controller 3210 may monitor read count values respectively corresponding to a plurality of select lines of the plurality of flash memories 3221 to 322n and control the plurality of flash memories 3221 to 322n to perform an operation of relocating the data stored in the first memory block based on the read count values satisfying a first threshold value. For example, the SSD controller 3210 may include the reliability management circuit 110 as described above with reference to FIG. 1.

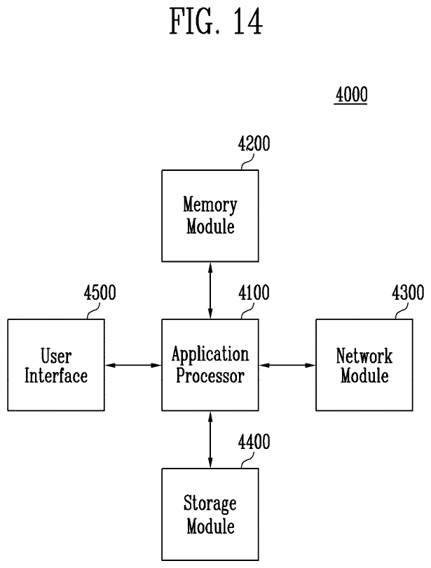

FIG. 14 is a block diagram illustrating a user system 4000 to which a storage device according to an embodiment of the present disclosure is applied.

Referring to FIG. 14, the user system 4000 may include an application processor 4100, a memory module 4200, a network module 4300, a storage module 4400, and a user interface 4500.

The application processor 4100 may run components included in the user system 4000, an Operating System (OS), or a user program. In an embodiment, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory, or a cache memory of the user system 4000. The memory module 4200 may include volatile RAMs such as DRAM, SDRAM, DDR SDRAM, DDR2 SDRAM, DDR3 SDRAM, LPDDR SDARM, LPDDR2 SDRAM, and LPDDR3 SDRAM or non-volatile RAMs such as PRAM, ReRAM, MRAM, and FRAM. In an embodiment, the application processor 4100 and the memory module 4200 may be packaged based on package-on-package (POP) and may then be provided as a single semiconductor package.

The network module 4300 may communicate with external devices. For example, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), Wimax, WLAN, UWB, Bluetooth, or WiFi communication. In an embodiment, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. In an embodiment, the storage module 4400 may be implemented as a non-volatile semiconductor memory device, such as a Phase-change RAM (PRAM), a Magnetic RAM (MRAM), a Resistive RAM (RRAM), a NAND flash memory, a NOR flash memory, or a NAND flash memory having a three-dimensional (3D) structure. In an embodiment, the storage module 4400 may be provided as a removable storage medium (i.e., a removable drive), such as a memory card or an external drive of the user system 4000.

For example, the storage module 4400 may include a plurality of non-volatile memory devices, and the plurality of non-volatile memory devices may operate in the same manner as the nonvolatile memory device 200 described above with reference to FIG. 1.

The user interface 4500 may include interfaces which input data or instructions to the application processor 4100 or output data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as a Liquid Crystal Display (LCD), an Organic Light Emitting Diode (OLED) display device, an Active Matrix OLED (AMOLED) display device, an LED, a speaker, and a motor.

According to an embodiment, the storage module 4400 may monitor read count values corresponding to the plurality of select lines, respectively, and may perform data relocation based on the read count values. For example, the storage module 4400 may include the reliability management circuit 110 as described above with reference to FIG. 1.

According to an embodiment of the present disclosure, a storage device having an improved operation speed and a method of operating the storage device may be provided.

As used herein, the terms “device” or “unit” refer to any combination of software, firmware, and/or hardware configured to provide the functions described in this specification. For example, software may be implemented as a software package, codes, and/or a set of instructions or a command, and hardware may include one or any combination or assembly of hardwired circuits, programmable circuits, state machine circuits, and/or firmware storing instructions executable by programmable circuits.

What is claimed is:

1. A storage device, comprising:
a non-volatile memory device including a first memory block coupled to a plurality of select lines; and
a controller configured to control an operation of the non-volatile memory device,
wherein the controller is configured to:
monitor read count values corresponding to the plurality of select lines, respectively, during a read operation of the first memory block of the non-volatile memory device, and
control the non-volatile memory device to perform an operation of relocating data stored in the first memory block, based on the read count values satisfying a first threshold value.

2. The storage device of claim 1, wherein the operation of relocating the data stored in the first memory block comprises at least one of a read reclaim operation and a garbage collection operation.

3. The storage device of claim 1, wherein the controller:
performs a test read operation on the first memory block, based on the read count values, and
controls the non-volatile memory device to perform the operation of relocating the data, based on a result of the test read operation.

4. The storage device of claim 3, wherein the controller controls the non-volatile memory device to perform the test read operation on the first memory block whenever one of the read count values reaches a first cycle.

5. The storage device of claim 3,
wherein the first memory block comprises a plurality of pages, and
wherein the controller controls the non-volatile memory device to perform the test read operation on at least one representative page of the plurality of pages.

6. The storage device of claim 3, wherein the controller:
reads first data of the first memory block and determines whether a number of error bits included in the first data satisfies a second threshold value is greater than or equal to a threshold value during the test read operation, and
controls the non-volatile memory device to perform the operation of relocating the data stored in the first memory block, based on whether the number of error bits satisfies the second threshold value.

7. The storage device of claim 1,
wherein the first memory block comprises a plurality of cell strings coupled between a plurality of bit lines and a source line,
wherein each of the plurality of cell strings comprises a drain select transistor coupled to one of the plurality of bit lines, a source select transistor coupled to the source line, and a plurality of memory cells coupled between the drain select transistor and the source select transistor, and
wherein the plurality of select lines comprise a plurality of source select lines each coupled to a gate electrode of the source select transistor included in each of the plurality of cell strings.

8. The storage device of claim 7,
wherein a plurality of memory cells included in each of the plurality of cell strings are coupled to a plurality of word lines, and
wherein the controller is configured to:
control the non-volatile memory device to perform the read operation on a first cell string of the plurality of cell strings by applying voltages to the plurality of word lines, and
monitor the read count values corresponding to the plurality of select lines, respectively, by counting a number of read operations corresponding to a source select line coupled to the first cell string.

9. The storage device of claim 7, wherein each of the plurality of source select lines is coupled to two or more different cell strings coupled to a same bit line among the plurality of cell strings.

10. A method of operating a storage device including a first memory block coupled to a plurality of select lines, the method comprising:
performing a read operation on the first memory block;
monitoring read count values corresponding to the plurality of select lines, respectively; and
relocating data stored in the first memory block, based on the read count values satisfying a first threshold value.

11. The method of claim 10, wherein the relocating the data comprises performing at least one of a read reclaim operation and a garbage collection operation on the data stored in the first memory block.

12. The method of claim 10, wherein the relocating the data comprises:
performing a test read operation on the first memory block based on the read count values; and
relocating the data stored in the first memory block, based on a result of the test read operation.

13. The method of claim 12, wherein the performing the test read operation is performed each time one of the read count values reaches the first cycle.

14. The method of claim 12,
wherein the first memory block comprises a plurality of pages, and
wherein the performing the test read operation comprises performing the test read operation on at least one representative page of the plurality of pages.

15. The method of claim 12,
wherein the performing the test read operation comprises reading first data of the first memory block and determining whether a number of error bits included in the first data satisfies a second threshold value, and
wherein the relocating the data comprises relocating the data stored in the first memory block, based on whether the number of error bits satisfies the second threshold value.

16. The method of claim 10,
wherein the first memory block comprises a plurality of cell strings coupled between a plurality of bit lines and a source line,
wherein each of the plurality of cell strings comprises a drain select transistor coupled to one of the plurality of bit lines, a source select transistor coupled to the source line, and a plurality of memory cells coupled between the drain select transistor and the source select transistor, and
wherein the plurality of select lines comprise a plurality of source select lines each coupled to a gate electrode of the source select transistor included in each of the plurality of cell strings.

17. The method of claim 16,
wherein a plurality of memory cells included in each of the plurality of cell strings are coupled to a plurality of word lines,
wherein the performing the read operation comprises applying voltages to the plurality of word lines to perform the read operation on a first cell string of the plurality of cell strings, and
wherein the monitoring the read count values comprises counting a number of read operations corresponding to a source select line coupled to the first cell string to monitor the read count values corresponding to the plurality of select lines, respectively.

18. The method of claim 16, wherein each of the plurality of source select lines is coupled to two or more different cell strings coupled to a same bit line among the plurality of cell strings.

19. A method of operating a storage device including a first memory block including a plurality of cell strings coupled to a plurality of select lines and a plurality of word lines, the method comprising:
applying a read voltage to a first word line of the plurality of word lines to perform a read operation on a first cell string;
increasing a first read count value for a first select line coupled to the first cell string; and
relocating data stored in the first memory block, based on the first read count value satisfying a threshold value.

20. The method of claim 19, wherein the plurality of cell strings are selectively coupled to a source line by a voltage applied to the plurality of select lines.
